(19) United States
(12) Patent Application Publication
(10) Pub. No.: US 2025/0040166 A1
(43) Pub. Date: Jan. 30, 2025

(54) Planar JFET Device with Reduced Gate Resistance

(71) Applicant: SEMICONDUCTOR COMPONENTS INDUSTRIES, LLC, Scottsdale, AZ (US)

(72) Inventor: Alexander Viktorovich BOLOTNIKOV, Niskayuna, NY (US)

(73) Assignee: SEMICONDUCTOR COMPONENTS INDUSTRIES, LLC, Scottsdale, AZ (US)

(21) Appl. No.: 18/358,367

(22) Filed: Jul. 25, 2023

(51) Int. Cl. H01L 29/66; H01L 29/06; H01L 29/10; H01L 29/16; H01L 29/78

(52) U.S. Cl. CPC H01L 29/66893; H01L 29/0692; H01L 29/1058; H01L 29/1066; H01L 29/1608; H01L 29/7832

(57) ABSTRACT

A junction field effect transistor (JFET) includes a drift region disposed on a substrate that includes a drain region of the JFET. A lower gate region is disposed on the drift region, a source region is disposed above the lower gate region, and an upper gate region at least partially surrounding the source region and extending laterally beyond the lower gate region is disposed above the source region. The upper gate region extends laterally beyond the lower gate region by a distance defining a gate offset width between the upper gate region and the lower gate region.

### RELATED APPLICATION

This application is related to U.S. patent application Ser. No. 18/066,738, filed on Dec. 15, 2022, which is incorporated by reference in its entirety herein.

### TECHNICAL FIELD

This description relates to semiconductor devices.

### BACKGROUND

In many transistor-based devices, multiple transistor cells are connected within an active area of a device. Each individual transistor cell may be considered to be a unit cell of the overall device, and the width of a unit cell may be referred to as a pitch of the device. Operational aspects of the overall device may be dictated by characteristics of the individual transistors included therein, as well as by the aggregated or composite characteristics of the multiple transistor cells within the active area.

For example, an on-state resistance of a transistor, also referred to as a source-drain on-state resistance, or R_{DSon}, may indicate an amount of current (e.g., drain current or Id) that exists for a corresponding drain voltage (e.g., a drain-source voltage, or Vds). A gate-source breakdown voltage, or BVgs, may refer to a reverse voltage at which the transistor exhibits a sudden rise of reverse current while the transistor is in an off-state. A gate resistance of the transistor, or Rg, may refer to an impedance the gate of the transistor presents to its gate drive. The gate resistance Rg is a measure of the switching losses and power efficiency of the transistor.

### SUMMARY

In a general aspect, a junction field effect transistor (JFET) includes a drift region disposed on a substrate that includes a drain region of the JFET. A lower gate region is disposed on the drift region, a source region is disposed above the lower gate region, and an upper gate region at least partially surrounding the source region and extending laterally beyond the lower gate region is disposed above the source region. The upper gate region extends laterally beyond the lower gate region by a distance defining a gate offset width between the upper gate region and the lower gate region.

In a general aspect, a junction field effect transistor (JFET) includes a substrate including a drain region of the JFET. A drift region is disposed on the substrate and a plurality of device cells are disposed in an array on the drift region. Each device cell includes a lower gate region disposed on the drift region, a source region disposed above the lower gate region, and an upper gate region at least partially surrounding the source region. The upper gate region extends laterally beyond the lower gate region by a distance defining a gate offset width between the upper gate region and the lower gate region. Each device cell further includes a channel region extending from the source region to the drain region passing through a space between the upper gate region and the lower gate region, a gate contact disposed over the upper gate region, and a gate terminal contact region disposed on a side of the array of the plurality of device cells. The gate contact disposed over the upper gate region in each of the plurality of device cells extends to and is connected to the gate terminal contact region.

In a general aspect, a method for forming a junction field effect transistor (JFET) includes disposing a drift region on substrate that includes a drain region of the JFET. The method further includes disposing a lower gate region on the drift region, disposing a source region above the lower gate region, and disposing an upper gate region at least partially surrounding the source region and extending laterally beyond the lower gate region by a distance defining a gate offset width between the upper gate region and the lower gate region.

In a general aspect, a method for forming a junction field effect transistor (JFET) includes disposing a drift region on substrate including a drain region of the JFET, and disposing a plurality of device cells in an array on the drift region. Each device cell includes a lower gate region disposed on the drift region, a source region disposed above the lower gate region, and an upper gate region at least partially surrounding the source region. The upper gate region extends laterally beyond the lower gate region to define a gate offset width between the upper gate region and the lower gate region. Each device cell further includes a channel region extending from the source region to the drain region passing through a space between the upper gate region and the lower gate region, and a gate contact disposed over the upper gate region.

The method further includes disposing a gate terminal contact region on a side of the array of the plurality of device cells. The gate contact disposed over the upper gate region in each of the plurality of device cells extends to and is connected to gate terminal contact region.

The details of one or more implementations are set forth in the accompanying drawings and the description below. Other features will be apparent from the description and drawings, and from the claims.

### BRIEF DESCRIPTION OF THE DRAWINGS

FIG. 1A illustrates a cross sectional view of two adjacent device cells of a planar junction field effect transistor (JFET) (taken along section line AA-AA in FIG. 2B).

FIG. 1B is an example graph of values of breakdown voltage (BV(V)) and Rds(on) of an example device as a function of the dopant concentration of a depletion-limiter region in the example device.

FIG. 2A illustrates a layout of a planar JFET semiconductor device.

FIG. 2B illustrates another layout of a planar JFET semiconductor device cross sectional view of the self-aligned JFET device of FIG. 1A.

FIG. 3 illustrates a cross sectional view of the planar JFET of FIG. 1A (taken along line BB-BB in FIG. 2B).

FIG. 4 illustrates a side perspective view of a three-dimensional section of a dual-gate planar JFET.

FIG. 5 illustrates a side perspective view of a three-dimensional section of another dual-gate planar JFET.

FIG. 6 illustrates an example method for forming a JFET.

FIG. 7 illustrates another example method for forming a JFET.

### DETAILED DESCRIPTION

The gate electrode and internal capacitances (e.g., Cgs, Ciss) of a junction field effect transistor (JFET) device form an RC like network to its gate drive, which is typically characterized by impedance. The real part of this impedance is referred to as the gate resistance Rg. The gate resistance Rg is caused by the finite resistance of the gate conductors, and the metal and contact structures that route a gate signal to external package leads of the device. For a JFET device, the gate resistance Rg of the gate electrodes, in general, depends on properties of the gate conductor materials (e.g., dopant level of the semiconductor gate material, the type of gate metal, etc.) used, the gate geometry, and the JFET device layout arrangement.

Planar JFET devices having a reduced pitch (e.g., less than 5 microns) and a reduced gate resistance Rg are disclosed herein. An example JFET device (e.g., a 650V SiC double-gate planar JFET) may include a semiconductor substrate including a drain region of the JFET, a drift region disposed on the semiconductor substrate, a lower (buried) gate region disposed on the drift region, and an upper gate region disposed above the lower gate. The JFET may include a source region having a lower source region that is disposed above the lower (buried) gate region and extends laterally along the lower (buried) gate region, and an upper source region disposed on the lower source region. The upper gate region is formed to at least partially surround the upper source region, and extends laterally beyond the lower (buried) gate region to define a gate offset width (or gate overlap width) between the upper gate region and the lower gate region.

The substrate, the drift region and the source region of the device may be of a first conductivity type (e.g., n-type) while the gate structures (e.g., the lower and upper gate regions may be of an opposite second conductivity type (e.g., p-type)). A channel region of the JFET can extend from the source region to the drain region passing through a space between the upper gate region and the lower (buried) gate region. Current flow between the source region and drain region of the device can be through the channel region.

The two gate structures (e.g., the upper gate region and the lower gate region) and the channel region (drift region) form respective p-n junctions. These p-n junctions can form depletion layers next to the respective gate structures even when no external voltages are applied. The widths (depth or thickness) of the depletion layers formed by the upper gate region and the lower (buried) gate region (with the oppositely doped drift region) are a function of the dopant concentrations of the regions and applied bias. The widths (depth or thickness) of the depletion layers formed by the upper gate region and the lower (buried) gate region can narrow a width of a portion of the channel region through which the device current (e.g., a majority carrier current) can flow. In instances where the upper gate region is of a large size (e.g., with a large a gate offset width over the lower gate region), the width of the depletion layer formed by the upper gate region can result in channel pinch-off in the JFET.

In accordance with the principles of the present disclosure, a size of the upper gate region and an amount of conductive material (e.g., gate contact material) placed over the upper gate region in a JFET are designed to reduce a gate resistance (Rg) of the device while preserving the blocking capability of the device. A depletion limiter region is disposed next to (e.g., in contact with, below) the upper gate region in the JFET to prevent channel pinch-off. The depletion limiter region may have a dopant concentration that limits the extent of the depletion layer that may be formed by the large size upper gate region needed to reduce Rg. The depletion limiter region may be disposed below the upper gate region, for example, beginning at an edge of the channel region and extending to the same width (lateral width) or a comparable width as the upper gate region.

A built-in potential of the p-n junctions formed at the upper gate region and depletion limiter region may cause formation of a depletion region in the device along, or across a thickness of, the channel region. The depletion limiter region may have a dopant concentration N_{depletion-limiter} that precludes the depletion limiter region from being fully depleted and thus preventing expansion of the depletion region below the upper gate region to pinch off the channel region of the device. In example implementations, the dopant concentration N_{depletion-limiter} of the depletion-limiter region may have a value that is higher than a dopant concentration N_{upper-drift} of upper portions of the drift region of the device. In other words, N_{depletion-limiter} is greater than N_{upper-drift} to preclude the depletion limiter region from being fully depleted.

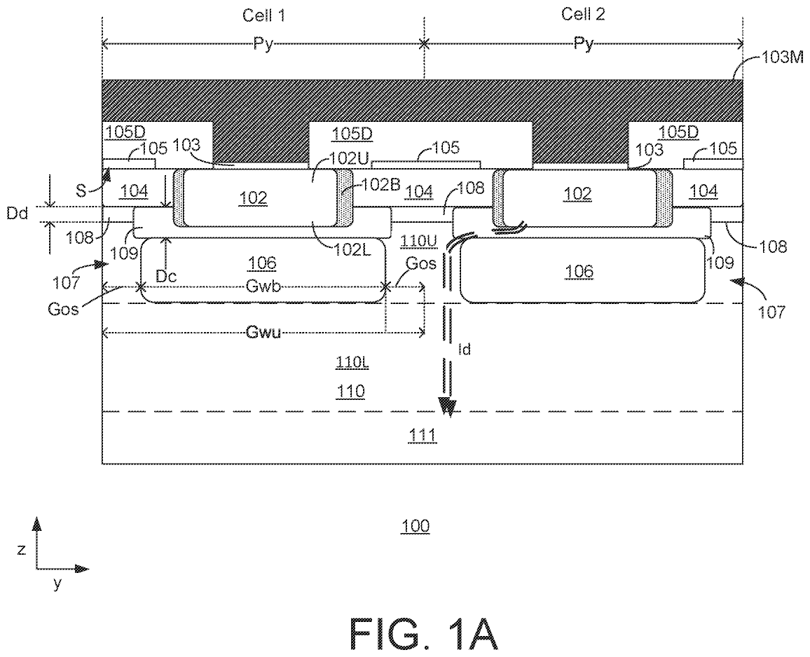

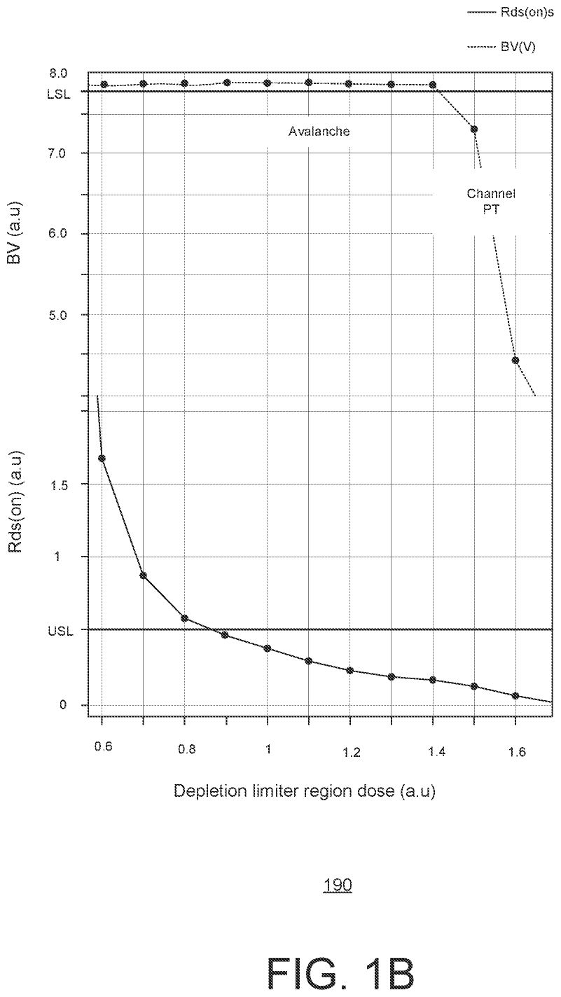

FIG. 1B shows an example graph 190 of values of breakdown voltage (BV(V)) and Rds(on)s of a JFET with reduced Rg as disclosed herein. Graph 190 shows BV(V) and Rds(on) as a function of the dopant concentration (N_{depletion-limiter}) of the depletion-limiter region in an example device. In graph 190, BV(V) and Rds(on)s are plotted in arbitrary units (a.u) on the y axis The dopant concentration (N_{depletion-limiter}) of the depletion-limiter region in the example is plotted on the x axis. In the graph, upper specification limits (USL) for Rds(on) and a lower specification limit (LSL) for BV(V) are marked on the y axis. As seen in the graph, when the dopant concentration (N_{depletion-limiter}) is below the USL (e.g., to the left on the x axis), channel is partially pinched off; and Rds(on) increases. When the dopant concentration (N_{depletion-limiter}) is higher than the USL (e.g., to the right on the x axis), the breakdown voltage (BV) decreases. As seen in graph 190, the design of the JFET satisfies both the Rds(on) and BV requirements over a wide range of N_{depletion-limiter} (e.g., the depletion limiter region dose from 0.9 to 1.4 (a.u.) provides a Rds(on) that is less than the corresponding USL and a BV that is higher than the corresponding LSL).

In example implementations, the depletion limiter region may have a height (depth or thickness) Dd that is less than a height (depth or thickness) Dc of the channel region between the upper and the lower gate regions. It will be noted that for visual clarity, these heights are not depicted to scale in FIG. 1A.

In example implementations, the depletion limiter region may be formed by an epitaxial process or by an ion implantation process. In some example implementations, the depletion limiter region may be formed as a part of the same epitaxy or implantation processes that may be used for doping the upper drift region or/and portion of the channel region.

The JFET structures described herein enable widening of the upper gate region and placement of additional conductive material over the upper gate region (thus reducing Rg) while at the same time keeping the JFET's blocking capability intact.

In the absence of depletion limiter region, an extension of the upper gate region beyond the channel region in the JFET semiconductor device and can result in channel pinch-off due to an increase (extension of) in the depletion region below the upper gate region in the upper drift region due to lower doping of such. Extending the channel region further beyond the lower gate region to overcome channel pinch-off can significantly increase electrical fields at the channel region-upper gate region interface during off-state operation. This increase in the electrical fields can reduce the blocking characteristics of the device when the device is in an off state. To avoid this reduction in the blocking characteristics, in example implementations of the disclosed JFET semiconductor devices, a dopant concentration (e.g., N_{depletion-limiter}) of the depletion limiter region may be kept below levels that can result in high electric fields in the channel region when the device is an off state. In example implementations, the dopant concentration N_{depletion-limiter} of the depletion-limiter region may have a value between the dopant concentration (e.g., N_{upper-drift}) of upper portions of the drift region of the device and the dopant concentration (e.g., N_{channel}) in the channel region. In other words, N_{upper-drift}<N_{depletion-limiter}<N_{channel}.

FIG. 1A shows a cross-sectional view of a portion of an example JFET 100 having gate structures with a low gate resistance Rg. JFET 100 may be a dual gate (double gate) device fabricated on a semiconductor substrate (e.g., a silicon (Si) substrate, a silicon carbide (SiC) substrate, a gallium nitride (GaN) substrate, a diamond (C) substrate, a gallium trioxide (Ga₂O₃) substrate, etc.).

The portion shown in FIG. 1A includes, for example, a cross sectional view in the y-z plane of two adjoining device cells (e.g., Cell 1 and Cell 2) that may repeat several times in JFET 100 with a pitch Py, for example, in the y direction.

As shown in FIG. 1A, JFET 100 may be fabricated on a semiconductor substrate 111 of a first conductivity type (e.g., a n+ doped semiconductor substrate) that includes a drain region (not shown) of the device. A drift region 110 (e.g., an n− doped region) is disposed on the semiconductor substrate. In each device cell (e.g., Cell 1, Cell 2), a source region 102 (e.g., a n− doped region) is disposed at about a top surface S of drift region 110. Drift region 110 may include an upper portion (e.g., portion 110U) that is more highly doped than a lower portion (e.g., portion 110L). Source region 102 may include an upper source portion 102U and a lower source portion 102L. Source region 102 may be at least partially surrounded by a low doped region 102B (e.g., a BVgs-enhancing region). Further, a buried or lower gate region 106 of a second conductivity type (e.g., a p− doped region) is formed in an upper portion of drift region 110 underneath the source region (e.g., source region 102). Lower gate region 106 may, for example, have a width Gwb (e.g., in the y-direction).

In JFET 100, an upper gate region (e.g., upper gate region 104) of the second conductivity type (e.g., a p− type) is disposed between the two source regions (e.g., source region 102) of two adjacent cells (e.g., Cell 1 and Cell 2). In each cell, source region 102 is least partially surrounded by upper gate region 104 of the opposite conductivity type (e.g., a p-type). In example implementations, an upper source portion 102U of source region 102 may be at least partially surrounded by a low doped region 102B (e.g., a BVgs-enhancing region), which is then at least partially surrounded by, or partially adjacent to, the upper gate region 104. A depletion-limiter region (e.g., depletion-limiter region 108) of the first conductivity type (e.g., n type) may be formed underneath at least a portion of the upper gate region 104 surrounding source region 102. Upper gate region 104 surrounding source region 102 may be a substantial portion (e.g., greater than 10%, 30%, 50%, 70%, etc.) of the top surface S of the device.

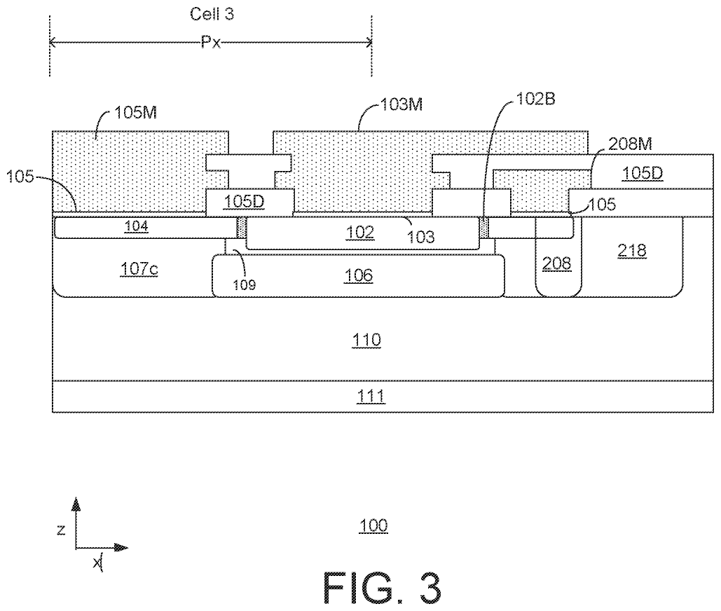

A p-doped region (e.g., gate contact region 107c, FIG. 3) may, for example, be implanted or diffused into portions of the upper portion (e.g., portion 110U) of drift region 110 to provide electrical connection to upper gate region 104 and lower gate region 106.

Depletion-limiter region 108 may have a dopant concentration (e.g., N_{depletion-limiter}) that is higher than a dopant concentration (e.g., N_{upper-drift}) of the upper portions (e.g., portion 110U) of drift region 110. As a result, a depletion region formed by the overlaying portion of upper gate region 104 in depletion-limiter region 108 may be narrower (i.e., less wide) (e.g., in the z direction)) than a depletion region (not shown) formed underneath a portion of upper gate region 104 directly overlaying the upper portions (e.g., portion 110U) of drift region 110.

In JFET 100, a source contact 103 (e.g., a metal, a metal silicide, a doped poly or combination of thereof) may be disposed on the top of the source region 102 and gate contact 105 (e.g., a metal, a metal silicide, a doped poly or combination of thereof) may be disposed on a top of upper gate region 104, for connection to external device terminals via metallization layers. FIG. 1A shows, for example, a source metallization layer 103M connecting the source contacts (e.g., source contact 103) in the device to an external terminal (not shown). A gate metallization layer (e.g., gate metallization layer 105M, FIG. 3) for connecting the gate contacts (gate contact 105) in the device is not visible in the view presented in FIG. 1A. It is however noted that gate contacts 105 and other portions (e.g., portions of source region 102 and upper gate region 104) of the JFET device are isolated from source metallization layer 103M by an insulating dielectric material layer 105D.

In example implementations, the dimensions (e.g., height, thickness, length) and the materials (e.g., dopant concentrations) of the gate structures (e.g., upper gate region 104, lower gate region 106, gate contact 105, and gate metallization) may be selected to achieve a low gate resistance Rg for JFET 100. In example implementations, the gate resistance Rg may for example, be less than a fraction of an ohm (e.g., less than 0.35 ohms or less than 0.5 ohms).

In some example implementations, the low Rg may be achieved by using a laterally-wide upper gate region 104. In the example implementations, upper gate region 104 may extend laterally beyond the lower gate region to define a gate offset width (e.g., gate offset width Gos) between the upper gate region and the lower gate region. The lower gate region may, for example, have a gate width Gwb (e.g., in the y direction). In example implementations, a lateral extent of the upper gate region may be larger than the gate width Gwb of the lower gate region. In FIG. 1, the upper gate region 104 extends along the whole device cell (including the width of source region 102) (e.g., in the y direction), for example, indicated as a cell pitch Py The gate offset width between the upper gate region and the lower gate region (on either side of source region 102 in the +y and the −y directions) is marked as Gos. In the example shown in FIG. 1, (2 Gos=(Py−Gwb)/2). In example implementations, the gate offset width Gos of the upper gate region may be greater than at least 10% of the gate width Gwb of the lower gate region. In example implementations, the gate offset width Gos may, for example, be in a range of about 0.1 microns to 1.0 micron (e.g., 0.2 microns).

In some instances, as shown in FIG. 1A, the width Gwu of the upper gate region may be the same as, or about the same as, the pitch Py of the device cells (Cell 1 or Cell 2).

With further reference to FIG. 1A, a channel (e.g., channel region 109) of the device may be defined as a space between overlapping portions of the lower gate region 106 and upper gate region 104. Channel region 109 extends from the source region to the drain region passing through a space between the upper gate region 104 and the lower gate region 106. Channel region 109 extends laterally (e.g., in the y direction) in the space between lower gate region 106 and the upper gate region (upper gate region 104) that at least partially surrounds source region 102. Channel region 109 may further extend laterally (e.g., in the +y and the −y directions) above lower gate region 106 and underneath the upper gate region (upper gate region 104) up to depletion-limiter region 108.

Channel region 109 may have a dopant concentration N_{channel} that is higher the dopant concentration (e.g., N_{depletion-limiter}) of depletion-limiter region 108 and is also higher than the dopant concentration (e.g., N_{upper-drift}) of upper portions (e.g., portion 110U) of the drift region of the device.

Current flow (e.g., current Id) from the source to the drain in the JFET device may initially flow in a lateral direction (e.g., in the y direction) through channel region 109 and then turn downwards (e.g., in the z direction) through drift region 110 to reach the drain region in semiconductor substrate 111.

In example implementations, the JFET devices (e.g., JFET 100) may be fabricated using industrial semiconductor processing techniques including, for example, thin film deposition (e.g., semiconductor epitaxy, dielectric deposition, metal deposition, etc.), photoresist coating, lithographic patterning and etching, ion implantation, dopant diffusion, etc. In example implementations, the fabrication process may include techniques (e.g., self-alignment techniques) that enable a device pitch that is smaller than can be obtained using conventional mask-based photolithography techniques, while avoiding misalignments that may lead to decreased BV and/or increased R_{DSon}. Consequently, JFET 100 (for a given active area and gate voltage) can provide an additional number of current channels, increased current rating, and reduced R_{DSon}, as compared to conventional devices, while retaining acceptable BV values.

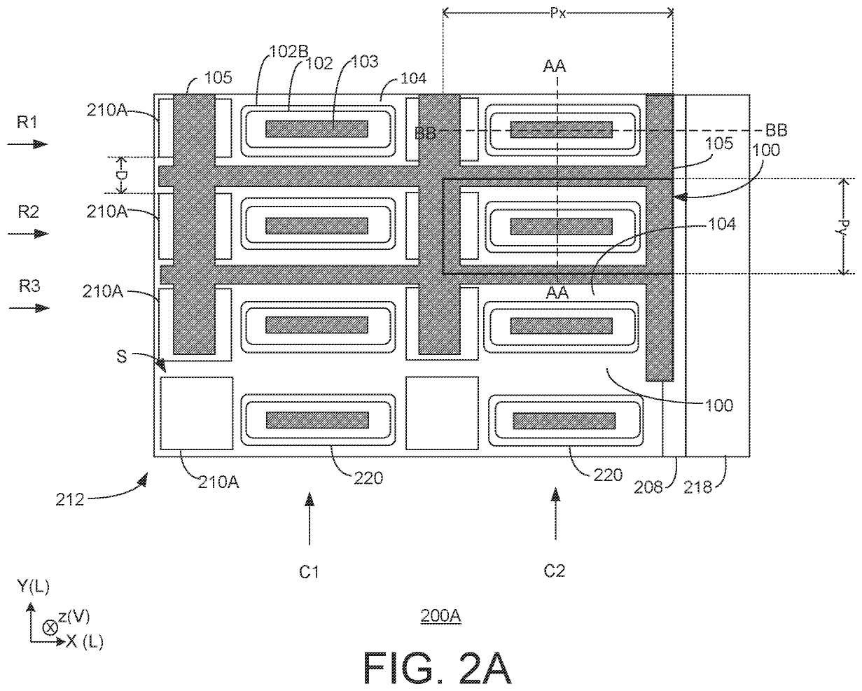

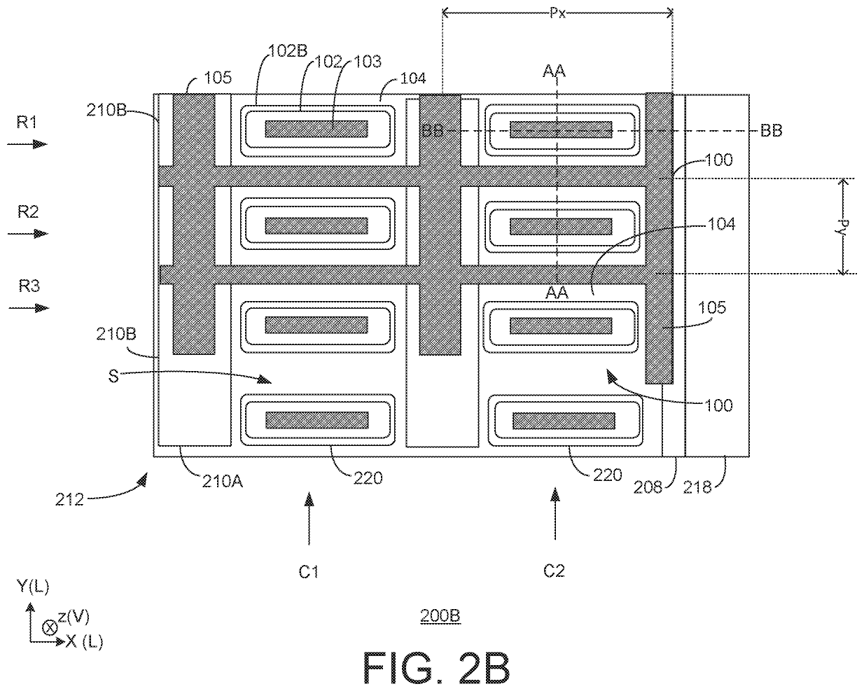

In example implementations, JFET 100 may include an array of device cells (JFET cells). Each JFET cell (e.g., a rectangular or stripe-shape cell) may define a unit cell of the JFET semiconductor device, with lines of unit cells extending, for example, in the x-direction and in the y-direction (FIGS. 2A and 2B). A pitch Py of JFET 100 may be defined as a distance (e.g., in the y-direction) between adjacent lines of unit cells, or, alternatively, as a width of a unit cell in the y-direction. Further, a pitch Px of JFET 100 may be defined as a distance (e.g., in the x-direction) between adjacent rows of unit cells, or, alternatively, as a width of a unit cell in the x-direction. Gate and source contacts to the JFET cell may be segmented and interdigitated (e.g., in the y-direction). Segments of the gate and source contacts may, for example, be disposed along a line of JFET cells in an alternating pattern (typically a long a non-current conductive direction, e.g., along the elongated portion of the stripe cell).

FIG. 2A and FIG. 2B illustrate top views of example layouts (e.g., layout 200A and layout 200B) of a JFET device fabricated on a semiconductor substrate (e.g., semiconductor substrate 111, FIG. 1). Layout 200A and layout 200B each include a plurality of individual JFET device cells, each referenced herein as JFET 100. Layout 200A and layout 200B include a layout of gate contacts and source contacts (e.g., the gate-source contact layout) of the JFET device cells.

As shown in FIG. 2A and FIG. 2B, the JFET semiconductor device may be formed in an active area 212 of the semiconductor substrate (e.g., semiconductor substrate 111, FIG. 1). Further, as shown in FIG. 2A and FIG. 2B, a termination region 218 of the second conductivity type (e.g., p-type) is defined adjacent to active area 212 in which the various JFET cells (JFET 100) are formed. It will be appreciated that FIG. 2A and FIG. 2B is a partial view of the active area 212 and the termination region 218. In example implementations, termination region 218 surrounds active area 212. For example, termination region 218 may define an outer perimeter of the active area 212. In some implementations, termination region 218 may include implants and/or trench structures to terminate electricals fields associated with operation of the various JFETs within active area 212 of the semiconductor device of FIG. 2A and FIG. 2B. Thus, termination region 218 may help maintain breakdown voltage (BV) of the JFETs (of FIG. 2A and FIG. 2B) close to a maximum BV limited by material properties. For instance, termination region 218 can prevent breakdown from occurring below a rated voltage of the JFET(s) 100, e.g., by terminating high electric fields during JFET's off-state operation.

Active area 212 may include an array (or grid) of JFET cells with the JFET cells (JFET 100) arranged in rows (e.g., rows R1, R2, R3, etc., extending in the x direction) and columns (e.g., columns C1, C2, etc., extending in the y direction). Gate contact regions (e.g., gate contact regions 210A, FIG. 2A; gate contact regions 210B, FIG. 2B) and source contact regions (e.g., source contact regions 220) of the JFET cells may be interdigitated (i.e., alternate) on surface S of the semiconductor substrate (e.g., semiconductor substrate 111, FIG. 1). The gate contact regions (represented, e.g., by gate contact region 210A, FIG. 2A; and gate contact region 210B, FIG. 2B) may correspond to a p-doped region (e.g., gate contact region 107 formed in drift region 110, FIG. 1). The gate contact regions (e.g., gate contact regions 210A, gate contact regions 210B) may, for example, be implanted or diffused into portions of an upper portion (e.g., portion 110U) of drift region 110 to provide electrical connection to lower gate region 106 buried in the JFET and upper gate region 104 (that is disposed on portions of surface S of active area 212).

In example layout 200A (FIG. 2A), the gate contact regions 210A may have a square or rectangular shape and may be interdigitated with the source contact regions 220 disposed in rows (e.g., rows R1, R2, R3, etc.). In other words, the positions of gate contact regions 210A may alternate with the positions of the source contact regions 220 in each row (e.g., rows R1, R2, R3, etc.), for example, along the x direction. In some example implementations, as shown in layout 200A (FIG. 2A), the gate contact regions 210A in the different rows (e.g., rows R1, R2, R3, etc.) may be separated from adjacent gate contact regions 210A in a same column (e.g., column C1 or column C2) by an inter-row distance D (e.g., in the y direction).

In some other example implementations, as shown in layout 200B (FIG. 2B), the inter-row distance D (e.g., in the y direction) between gate contact regions may be set to zero. In other words, gate contact regions 210A in the different rows of FIG. 2A may be combined or merged with adjacent gate contact regions in a same column (e.g., column C1 or column C2) to form an extended gate contact region (e.g., gate contact region 210B) that extends over all or several rows in a column (e.g., in column C1 and or column C2).

In the example layouts of FIG. 2A and FIG. 2B, each of a plurality of source contact regions 220 includes a source region (e.g., source region 102 of a first conductivity type, e.g., n-type) of a JFET 100. Each source region 102 is illustrated as being at least partially surrounded by a BVgs-enhancing low-doped region 102B of the first conductivity type (e.g., n-type). Further, each BVgs-enhancing low-doped region 102B (surrounding source region 102) is at least partially surrounded by an upper gate region 104 of a second conductivity type (e.g., p-type) that is disposed on portions of surface S of active area 212.

An electrically conductive source contact (e.g., source contact 103) is disposed over each of the plurality of source regions (e.g., source region 102) shown in FIG. 2A and FIG. 2B to provide electrical connection to the source regions of the JFET device.

Further, as shown in FIG. 2A and FIG. 2B, an electrically conductive gate contact (e.g., gate contact 105) is disposed over each of the plurality of gate contact regions 210A shown in FIG. 2A and gate contact regions 210B shown in FIG. 2B to provide electrical connection to the gates (i.e., upper gate regions 104 and lower gate region 106) of the JFET device.

Not visible in the top views of FIG. 2A and FIG. 2B but shown and described previously, e.g., with respect to FIG. 1, is a lower (buried) gate (e.g., lower gate region 106 in FIG. 1). In other words, in the top views of FIG. 2A and FIG. 2B, upper gate region 104, BVgs-enhancing low-doped region 102B and source region 102 are vertically above, and obscure a view of, the lower (buried) gate (e.g., the lower gate region 106 of FIG. 1).

In example implementations, the gate contacts (e.g., gate contact 105) disposed over gate contact regions 210A (FIG. 2A) and gate contact regions 210B (FIG. 2B) may extend over surface S while in contact with upper gate region 104 that at least partially surrounds source region(s) 102. The gate contacts 105 in each of the device cells may, for example, extend over surface S to a gate terminal contact region 208 next to termination region 218. Layout 200A (FIG. 2A) layout 200B (FIG. 2B) show, for example, the gate contacts (gate contacts 105) disposed on the gate contact regions (e.g., gate contact region 210A, gate contact region 210B) extending in lateral strips (in the x-direction) on surface S of upper gate region 104 and connecting to gate terminal contact region 208.

FIG. 3 illustrates a cross sectional view of a device cell (e.g., Cell 3) in the planar JFET of FIG. 1A (taken along line BB-BB in FIG. 2B). Cell 3, as shown in FIG. 3, may be a device cell adjacent to gate terminal contact region 208 next to termination region 218. In the example of FIG. 3, the gate contacts (e.g., gate contact 105) are connected by a gate metallization layer 105M (omitted in FIG. 1A for the sake of visibility). Gate metallization layer 105M includes gate terminal contact metallization 208M. Gate metallization layer 105M including gate terminal contact metallization 208M are illustrated as being positioned to enable electrical contact with both the upper gate region 104 and the lower gate region 106, using gate contact region 107. Insulating dielectric material layer(s) 105D are further illustrated as providing insulation between source metallization layer 103M and gate metallization layer 105M and between source metallization layer 103M and gate terminal contact region 208.

A single common gate voltage may be applied (e.g., via gate terminal contact region 208) to control all the individual JFET cell 100 of the JFET device of FIG. 1, FIG. 2A. FIG. 2B and FIG. 3.

In the example FETs described above, the gate contact material (e.g., gate contact 105) is disposed on surface S not only directly above gate contact regions 210A or gate contact region 210B but is also disposed above portions of upper gate region 104 that at least partially surround the source regions (e.g., source region 102). An increase in the area of the gate contacts in the planar JFETs (e.g., JFET 100) described above is enabled by the use of large size upper gate regions (upper gate region 104) with the concurrent use of the depletion-limiter regions (e.g., depletion-limiter region 108) to avoid channel pinch-off and deterioration of the breakdown characteristics of the device.

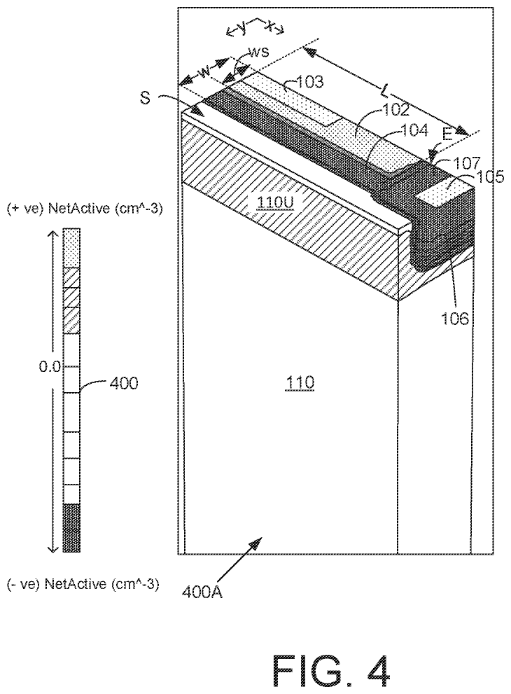

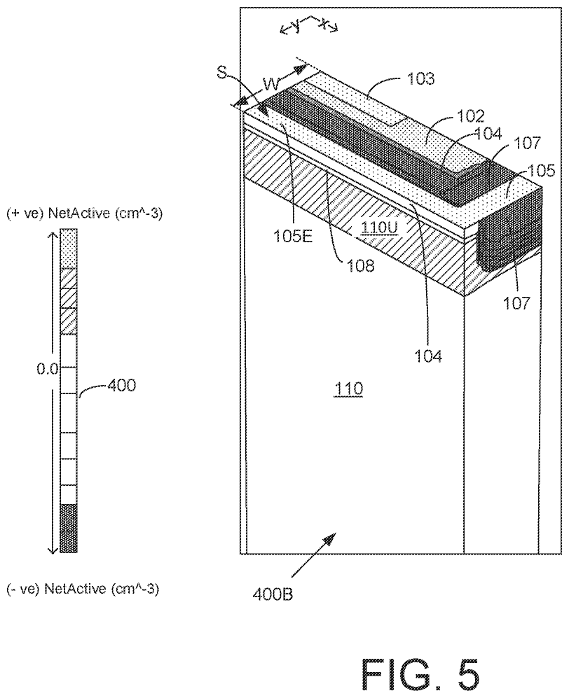

FIG. 4 shows a side perspective view of a three-dimensional section of a dual-gate planar JFET (e.g., JFET 400A) without extended gate contacts running along sides of the source contacts. FIG. 5 shows a side perspective view of a three-dimensional section of another dual-gate planar JFET (e.g., JFET 400B) with extended gate contacts 105E running along sides of the source contacts.

JFET 400A and JFET 400B may be fabricated in SiC semiconductor material. Nitrogen (N) may be used as an n-type dopant and aluminum (Al) may be used as a p-type dopant in forming the various doped regions of the JFETs. A key 400 included in both FIG. 4 and FIG. 5 shows a correspondence between example dopant concentrations (e.g., NetActive (cm\hat{ }−3)) and the hatching types used in the figures to depict various regions of the JFETs (e.g., JFET 400A and JFET 400B). Key 400 may represent the dopant concentration on a logarithm scale between, for example, −2.0 e+19 atoms/cc and +2.0 e+19 atoms/cc. Metal silicide may, for example, be used as the gate contact material for making ohmic contact with the gate contact regions of the JFETs.

As shown in FIG. 4, a generally rectangular source region (e.g., source region 102) is disposed about a top surface S of drift region 110 of JFET 400A. Source region 102 may have a length L (e.g., in the x direction) and a width ws (e.g., in the y direction). A source contact (e.g., source contact 103) is disposed on source region 102. In JFET 400A, the dual gate structures (e.g., upper gate region 104, and lower (buried) gate region 106) may have about the same width w (e.g., in the y direction). The dual gate structures are connected to a gate contact 105 via gate contact region 107 disposed at an end of source region 102. In the example shown in FIG. 4, source contact 103 and gate contact 105 are interdigitated (i.e., in other words, alternate) in the x direction. There is no other gate contact disposed on surface S of JFET 400A.

As shown in FIG. 5, a generally rectangular source region (e.g., source region 102) is disposed about a top surface S of drift region 110 of JFET 400B. Source region 102 may have a length L (e.g., in the x direction) and a width w (e.g., in the y direction). A source contact (e.g., source contact 103) is disposed on source region 102. In the dual gate structures of the device, upper gate region 104 may have a width W (in the y direction). A portion of the depletion limiting region (depletion-limiter region 108, FIG. 1A) is visible below upper gate region 104 is in the view shown in FIG. 5. The dual gate structures are connected to gate contact 105 via gate contact region 107 disposed at an end of source region 102. In the example shown in FIG. 5, a gate contact material leading to gate contact 105) is also disposed on upper gate region 104 on surface S along and at least partially surrounding source region 102. FIG. 5 shows, for example, a strip of gate contact material (e.g., gate contact 105E) disposed on surface S along a side of the source region in the x direction and along a side of the source region in the y direction. This additional gate contact material (gate contact 105E) reduces the gate resistance Rg of JFET 400B compared to the gate resistance Rg of JFET 400A (FIG. 4), which has gate contact 105 limited to gate contact region 107.

In example implementations, JFET 400A and JFET 400B may be configured, for example, as 650V SiC normally-on JFETs.

TABLE 1 below lists example values of the device parameters (e.g., gate resistance Rg (ohms); gate capacitance C (farads); and switching time constants RC (seconds) and 3RC (seconds)) of example 20 mOhm/650V SiC normally-on JFETs (e.g., JFET 400A, FIG. 4; and JFET 400B, FIG. 5) for different Vgs (volts).

TABLE 1

| | JFET 400A | | | | JFET 400B | | | |
|---|---|---|---|---|---|---|---|---|
| Vgs (V) | Rg (Ohm) | C(F) | RC(s) | 3RC(s) | Rg(Ohm) | C(F) | RC(s) | 3RC(s) |
| 1.E−03 | 1.22 | 6.29E−09 | 7.66E−09 | 2.30E−08 | 0.224 | 7.80E−09 | 1.75E−09 | 5.24E−09 |
| 1 | 1.25 | 4.91E−09 | 6.12E−09 | 1.84E−08 | 0.222 | 6.29E−09 | 1.39E−09 | 4.18E−09 |
| 10 | 2.21 | 2.36E−09 | 5.21E−09 | 1.56E−08 | 0.344 | 2.45E−09 | 8.44E−10 | 2.53E−09 |
| Average | | | 6.33E−09 | 1.90E−08 | | | 1.33E−09 | 3.99E−09 |

In TABLE 1, the values of the device parameters of the JFETs for different Vgs are shown in different rows (i.e., for Vgs=1E −03 volts, Vgs=1 volt, and Vgs=10 volts) under the column headings Rg (Ohm), C(F), RC(s) and 3RC(s). For example, for JFET 400A (FIG. 4) and Vgs=10 volts, TABLE 1 shows Rg=2.21 Ohm, C=2.36E-09F, RC=5.21E-09s, and 3RC=1.56E-08s. For JFET 400B (FIG. 5) and Vgs=10 volts, TABLE 1 shows Rg=0.344 Ohm, C=2.45E-09F, RC=8.44E-10s, and 3RC=2.53E-09s. Thus, JFET 400B with the widened upper gate region and the additional gate contact on the top surface S of the device may have a gate resistance Rg that is about 6× lower than the gate resistance Rg of JFET 400A (e.g., for JFET 400B, at Vgs=10 volts, Rg may be 0.5 ohms or less). Further, as indicated by the RC time constants shown in TABLE 1, JFET 400B may have faster turn-on/-off than JFET 400A by a factor of 8×.

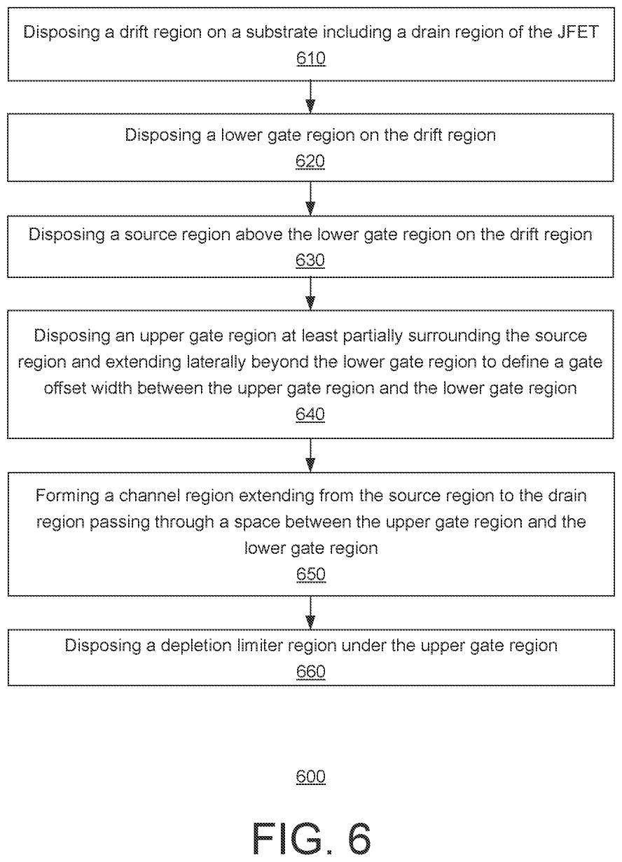

FIG. 6 illustrates an example method 600 for forming a Junction Field Effect Transistor (JFET).

Method 600 includes disposing a drift region on a substrate including a drain region of the JFET (610), disposing a lower gate region on the drift region (620), disposing a source region above the lower gate region (630), and disposing an upper gate region at least partially surrounding the source region and extending laterally beyond the lower gate region to define a gate offset width between the upper gate region and the lower gate region (640).

Method 600 further includes forming a channel region extending from the source region to the drain region passing through a space between the upper gate region and the lower gate region (650), and disposing a depletion limiter region under the upper gate region (660). The depletion limiter region limits the width (thickness) of a depletion layer formed under the upper gate region extending laterally beyond the lower gate region to preclude pinching off the channel region. The depletion limiter region has a depth that is less than a depth of the channel region between the upper gate region and the lower gate region. In example implementations, the depletion limiter region has a doping concentration that is greater than a doping concentration of the drift region and less than a doping concentration of the channel region.

Method 600 may further include forming a gate contact region that is in contact with the upper gate region and the lower gate region to provide a common gate contact to the upper gate region and the lower gate region.

The various disposing and forming steps (e.g., steps 610-660) in method 600 may be performed by ion implantation and/or doped epitaxy. In example implementations, the substrate may be a silicon carbide (SiC) substrate, nitrogen (N) may be used as a n-type dopant (e.g., for the drift region and the source region), and aluminum (Al) may be used as p-type dopant (e.g., for the upper and lower gate regions).

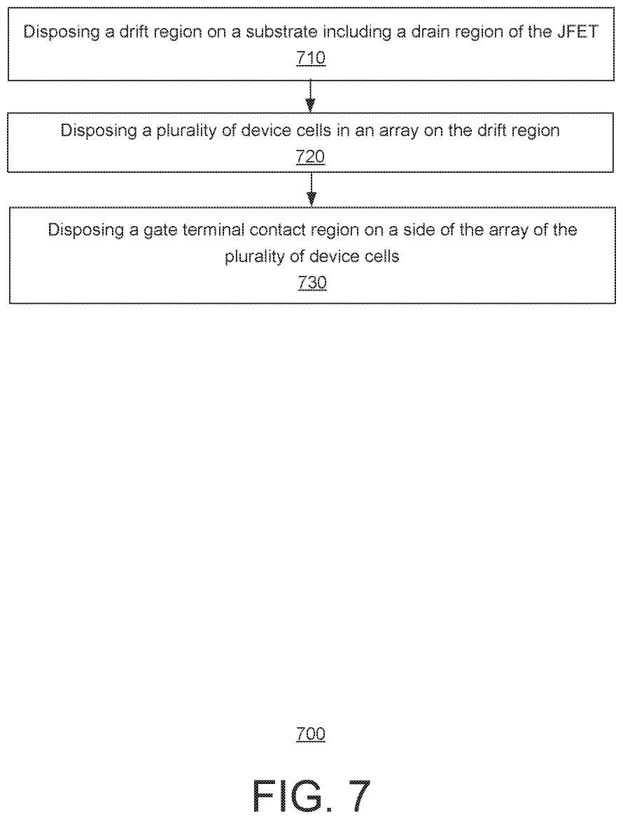

FIG. 7 illustrates an example method 700 for forming a Junction Field Effect Transistor (JFET).

Method 700 includes disposing a drift region on a substrate including a drain region of the JFET (710), and disposing a plurality of device cells in an array on the drift region (720). Each device cell in the array includes a lower gate region disposed on the drift region, a source region disposed above the lower gate region, and an upper gate region at least partially surrounding the source region. The upper gate region extends laterally beyond the lower gate region to define a gate offset width between the upper gate region and the lower gate region. Each device cell further includes a channel region extending from the source region to the drain region. The channel region passes through a space between the upper gate region and the lower gate region, and a gate contact disposed over the upper gate region.

Method 700 further includes disposing a gate terminal contact region on a side of the array of the plurality of device cells (730). The gate contact disposed over the upper gate region in each of the plurality of device cells extends to and are connected the gate terminal contact region.

Method 700 further includes, in each device cell, forming a gate contact region that is in contact with the upper gate region and the lower gate region to provide a common gate contact to the upper gate region and the lower gate region in each device cell.

In method 700, the upper gate region is disposed between two source regions of two adjacent device cells.

The various disposing and forming steps (e.g., steps 710-730) in method 700 may be performed by ion implantation, diffusion and/or doped epitaxy. In example implementations, the substrate may be a silicon carbide (SiC) substrate, nitrogen (N) may be used as a n-type dopant (e.g., for the drift region and the source region), and aluminum (Al) may be used as p-type dopant (e.g., for the upper and lower gate regions).

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A junction field effect transistor (JFET), comprising:
a drift region disposed on a substrate, the substrate including a drain region of the JFET;
a lower gate region disposed on the drift region;
a source region disposed above the lower gate region; and
an upper gate region at least partially surrounding the source region and extending laterally beyond the lower gate region by a distance defining a gate offset width between the upper gate region and the lower gate region.

2. The JFET of claim 1, further comprising:
a channel region extending from the source region to the drain region passing through a space between the upper gate region and the lower gate region;
a channel length defined by an overlap of the upper and lower gate regions;
a depletion limiter region disposed under the upper gate region, the depletion limiter region limiting a width of a depletion region formed under the upper gate region extending laterally beyond the lower gate region to preclude pinching off the channel region; and
a gate contact disposed on the upper gate region.

3. The JFET of claim 2, wherein the depletion limiter region has a depth that is less than a depth of the channel region between the upper gate region and the lower gate region.

4. The JFET of claim 2, wherein the depletion limiter region has a doping concentration that is greater than a doping concentration of the drift region and less than a doping concentration of the channel region.

5. The JFET of claim 1, further comprising:
a gate contact region that is in contact with the upper gate region and the lower gate region to provide a common gate contact to the upper gate region and the lower gate region.

6. The JFET of claim 5, wherein a source contact is disposed on the source region, and the source contact and the common gate contact are disposed alternately in a layout of the JFET.

7. The JFET of claim 1, wherein the substrate is a silicon carbide (SiC) substrate.

8. The JFET of claim 1, wherein the gate overlap width between the upper gate region and the lower gate region is 0.2 microns or greater.

9. The JFET of claim 1, wherein the JFET is normally on.

10. A junction field effect transistor (JFET), comprising:
a substrate including a drain region of the JFET;
a drift region disposed on the substrate; and
a plurality of device cells disposed in an array on the drift region, with each device cell including:
a lower gate region disposed on the drift region;
a source region disposed above the lower gate region;
an upper gate region at least partially surrounding the source region, and extending laterally beyond the lower gate region by a distance defining a gate offset width between the upper gate region and the lower gate region;
a channel region extending from the source region to the drain region passing through a space between the upper gate region and the lower gate region;
a gate contact disposed over the upper gate region; and
a gate terminal contact region disposed on a side of the array of the plurality of device cells, the gate contact disposed over the upper gate region in each of the plurality of device cells extending to and being connected to the gate terminal contact region.

11. The JFET of claim 10, wherein each device cell includes a gate contact region that is in contact with the upper gate region and the lower gate region to provide a common gate contact to the upper gate region and the lower gate region in each device cell.

12. The JFET of claim 10, wherein the upper gate region is disposed between two source regions of two adjacent device cells.

13. The JFET of claim 10, further comprising:
a depletion limiter region disposed under the upper gate region, the depletion limiter region limiting a width of a depletion layer formed under the upper gate region extending laterally beyond the lower gate region.

14. The JFET of claim 10, wherein the substrate is a silicon carbide (SiC) substrate.

15. The JFET of claim 14, wherein, at a gate to source voltage of 10 V, an input gate resistance of the JFET is 0.5 ohms or less.

16. The JFET of claim 10, wherein a pitch of the JFET defined between adjacent device cells is 5 microns or less.

17. The JFET of claim 11, wherein the overlap between the upper and lower gates is 0.2 microns or greater.

18. A method for forming a junction field effect transistor (JFET), the method comprising:
disposing a drift region on substrate including a drain region of the JFET;
disposing a lower gate region on the drift region;
disposing a source region above the lower gate region; and
disposing an upper gate region at least partially surrounding the source region and extending laterally beyond the lower gate region by a distance defining a gate offset width between the upper gate region and the lower gate region.

19. The method of claim 18, further comprising:
forming a channel region extending from the source region to the drain region passing through a space between the upper gate region and the lower gate region; and
disposing a depletion limiter region under the upper gate region, the depletion limiter region limiting a width of a depletion layer formed under the upper gate region extending laterally beyond the lower gate region.

20. The method of claim 19, wherein the depletion limiter region has a depth that is less than a depth of the channel region between the upper gate region and the lower gate region, and the depletion limiter region has a doping concentration that is greater than a doping concentration of the drift region and less than a doping concentration of the channel region.

21. The method of claim 18, further comprising:
forming a gate contact region that is in contact with the upper gate region and the lower gate region to provide a common gate contact to the upper gate region and the lower gate region.

22. A method for forming a junction field effect transistor (JFET), the method comprising:
disposing a drift region on substrate including a drain region of the JFET;
disposing a plurality of device cells in an array on the drift region, each device cell including:
a lower gate region disposed on the drift region,
a source region disposed above the lower gate region,
an upper gate region at least partially surrounding the source region, and extending laterally beyond the lower gate region to define a gate offset width between the upper gate region and the lower gate region,
a channel region extending from the source region to the drain region passing through a space between the upper gate region and the lower gate region, and
a gate contact disposed over the upper gate region; and
disposing a gate terminal contact region on a side of the array of the plurality of device cells, the gate contact disposed over the upper gate region in each of the plurality of device cells extending to and being connected the gate terminal contact region.

23. The method of claim 22, in each device cell, forming a gate contact region that is in contact with the upper gate region and the lower gate region to provide a common gate contact to the upper gate region and the lower gate region in each device cell.

24. The JFET of claim 22, wherein the upper gate region is disposed between two source regions of two adjacent device cells.
